(19) United States
(12) Patent Application Publication
(10) Pub. No.: US 2019/0024232 A1
(43) Pub. Date: Jan. 24, 2019

(54) SUBSTRATE PROCESSING APPARATUS AND SUBSTRATE RETAINER

(71) Applicant: HITACHI KOKUSAI ELECTRIC INC., Tokyo (JP)

(72) Inventors: Tetsuya KOSUGI, Toyama-shi (JP); Hitoshi MURATA, Toyama-shi (JP); Shingo NOHARA, Toyama-shi (JP); Atsushi HIRANO, Toyama-shi (JP)

(73) Assignee: HITACHI KOKUSAI ELECTRIC INC., Tokyo (JP)

(21) Appl. No.: 16/034,959

(22) Filed: Jul. 13, 2018

(30) Foreign Application Priority Data
Jul. 14, 2017 (JP) 2017-138211
May 29, 2018 (JP) 2018-102179

(51) Int. Cl. C23C 16/458; C23C 16/46

(52) U.S. Cl. CPC C23C 16/4587; C23C 16/46

(57) ABSTRACT

To reduce a temperature deviation on a surface of a substrate and shorten a temperature recovery time on the surface of the substrate, a substrate processing apparatus is provided. The substrate processing apparatus includes a substrate retainer configured to accommodate a plurality of substrates and heat insulating plates; a reaction tube within the substrate retainer; and a heating mechanism configured to heat the plurality of substrates, wherein the substrate retainer includes a substrate processing region where the plurality of substrates are accommodated and a heat insulating plate region where the heat insulating plates are accommodated. A reflectivity of each of the first heat insulating plates is accommodated in an upper layer portion of the heat insulating plate region and is higher than a reflectivity of each of the second heat insulating plates accommodated in a region other than the upper layer portion of the heat insulating plate region.

### CROSS-REFERENCE TO RELATED PATENT APPLICATION

This non-provisional U.S. patent application claims priority under 35 U.S.C. § 119 of Japanese Patent Application No. 2017-138211, filed on Jul. 14, 2017, in the Japanese Patent Office, and Japanese Patent Application No. 2018-102179, filed on May 29, 2018, in the Japanese Patent Office, the entire contents of which are hereby incorporated by reference.

### BACKGROUND

### 1. Field

The present disclosure relates to a substrate processing apparatus and a substrate retainer.

### 2. Description of the Related Art

A semiconductor manufacturing apparatus is an example of a substrate processing apparatus. It is known that a vertical apparatus is as an example of the semiconductor manufacturing apparatus. In the vertical apparatus, a substrate retainer in which a plurality of substrates is accommodated in multiple stages is brought into a process chamber, the plurality of substrates is heated, and a process gas is supplied into the heated substrates in the process chamber, and thus a film is formed on the plurality of substrates.

It is required to reduce a thermal budget (thermal history) when a substrate is heated. For example, in order to reduce a temperature variation on a surface of the substrate after rapid temperature rise, a plurality of plate-shaped heat insulating members (hereinafter referred to as “heat insulating plates”) is provided below the substrate. The heat insulating plate thermally insulates a furnace opening portion of a reaction tube.

However, when the number of the heat insulating plates is small, a temperature variation on the surface of the substrate accommodated below the substrate retainer is degraded. When the number of the heat insulating plates is large, a temperature recovery time on the surface of the substrate, in which the temperature variation on the surface of the substrate accommodated below the substrate retainer is stabilized, is increased.

### SUMMARY

Described herein is a technique capable of reducing a temperature deviation on a surface of a substrate and shortening a temperature recovery time on the surface of the substrate.

According to one aspect of the technique described herein, there is provided a configuration of a substrate processing apparatus including a substrate retainer configured to accommodate a plurality of substrates and a plurality of heat insulating plates; a reaction tube in which the substrate retainer is accommodated; and a heating mechanism configured to heat the plurality of substrates accommodated in the substrate retainer, wherein the substrate retainer includes a substrate processing region in which the plurality of substrates are accommodated and a heat insulating plate region in which the plurality of heat insulating plates are accommodated, and a reflectivity of each of first heat insulating plates accommodated in an upper layer portion of the heat insulating plate region among the plurality of heat insulating plates is higher than a reflectivity of each of second heat insulating plates accommodated in a region other than the upper layer portion of the heat insulating plate region among the plurality of heat insulating plates.

### BRIEF DESCRIPTION OF THE DRAWINGS

FIG. 1 is a vertical sectional view showing a substrate processing apparatus according to an embodiment described herein.

FIG. 2 is a vertical sectional view showing a portion of the substrate processing apparatus according to the embodiment.

FIG. 3 is a view showing a hardware configuration of a controller of the substrate processing apparatus according to the embodiment.

FIG. 4 is a view showing the vicinity of a heat insulating plate region of a substrate retainer according to the embodiment.

FIGS. 5A and B are views showing a transfer device and a substrate retainer according to the embodiment.

FIG. 6 is a flowchart of a substrate processing according to the embodiment.

FIG. 7 is a view showing the vicinity of a heat insulating plate region of a substrate retainer according to a first modified example.

FIG. 8 is a view showing the vicinity of a heat insulating plate region of a substrate retainer according to a second modified example.

FIG. 9 is a view showing experimental results in which a plurality of heat insulating plates is combined.

FIG. 10 is a graph showing experimental results in a case in which the substrate processing is performed with the combination of FIG. 9, which is a view showing a relationship between an accommodated position of a substrate and a temperature deviation on a surface of the substrate.

FIG. 11 is a graph showing experimental results in a case in which the substrate processing is performed with the combination of FIG. 9, which is a view showing a relationship between an accommodated position of a substrate and a temperature recovery time on a surface of the substrate.

FIGS. 12A-D are views showing an example of a heat insulating plate region formed by combining a plurality of heat insulating plates.

FIG. 13 is a graph showing a relationship between a time and a temperature characteristic of a substrate when a heat insulating portion shown in FIG. 12 is used.

### DETAILED DESCRIPTION

Hereinafter, embodiments will be described with reference to the drawings.

### Embodiment

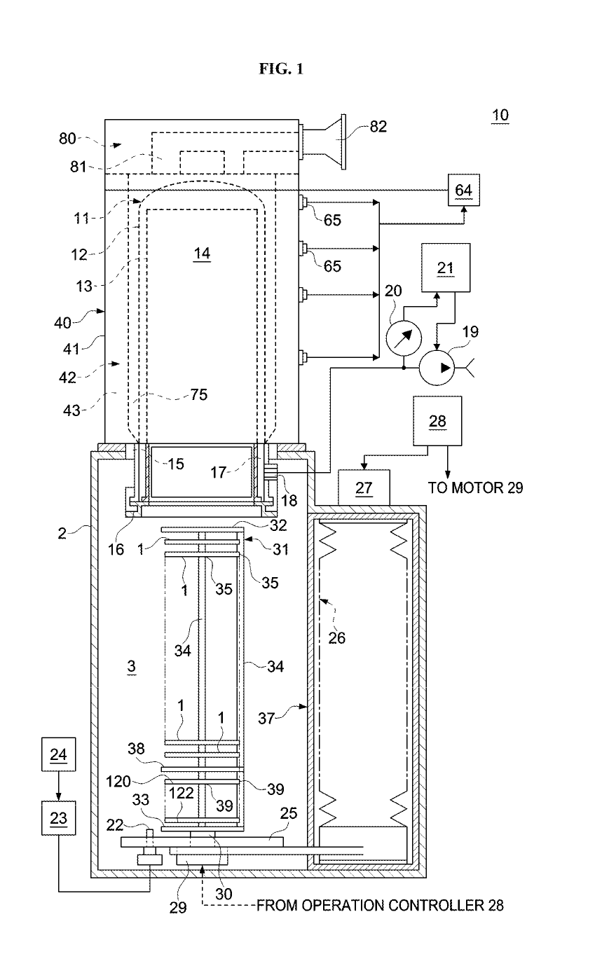

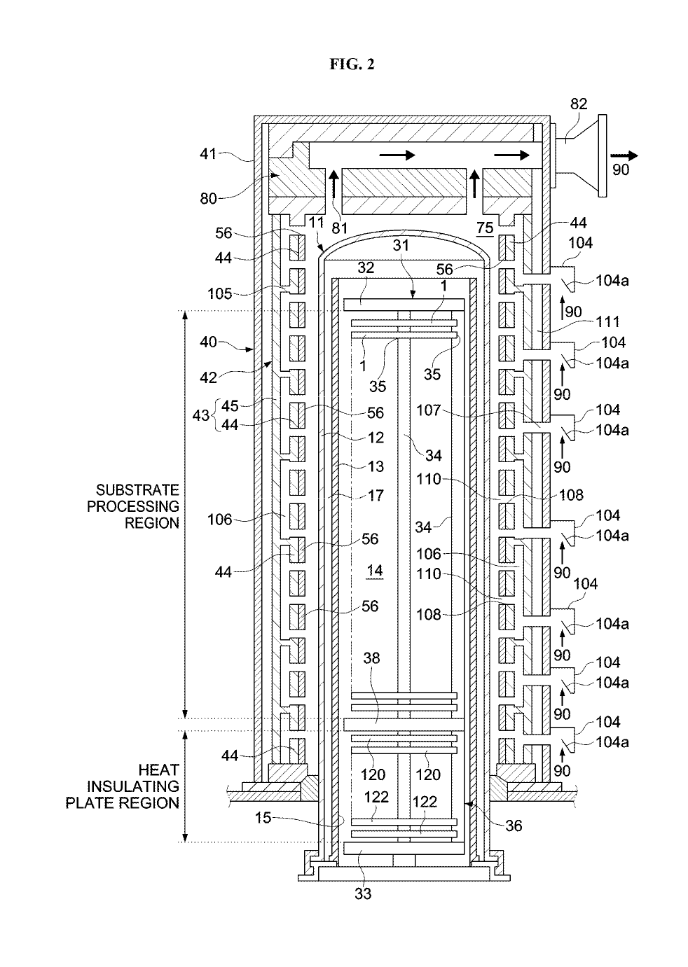

As illustrated in FIGS. 1 and 2, a substrate processing apparatus according to an embodiment is constituted by a batch type vertical apparatus in which a film-forming process according to a manufacturing method of an integrated circuit (IC) is performed.

A substrate processing apparatus 10 shown in FIG. 1 includes a process tube 11 serving as a vertical reaction tube. The process tube 11 includes an outer tube 12 serving as an outer reaction tube and an inner tube 13 serving as an inner reaction tube. The outer tube 12 is provided concentrically with the inner tube 13. The outer tube 12 is made of a heat-resistant material such as quartz (SiO₂). The outer tube 12 is cylindrical with a closed upper end and an open lower end. The inner tube 13 is cylindrical with open upper and lower ends. A process chamber 14 is defined by the hollow cylindrical portion of the inner tube 13. A boat 31 serving as a substrate retainer to be described later is loaded into the process chamber 14. The lower end opening of the inner tube 13 serves as a furnace opening portion 15 for loading the boat 31 into the process chamber 14 and unloading the boat 31 from the process chamber 14. As will be described later, the boat 31 is configured to accommodate a plurality of substrates 1 (hereinafter also referred to as “wafers”) vertically arranged in multiple stages. Therefore, the inner diameter of the inner tube 13 is larger than the maximum outer diameter of the substrate 1 to be processed. For example, the maximum outer diameter of the substrate 1 is 300 mm.

The lower end portion between the outer tube 12 and the inner tube 13 is airtightly sealed by a manifold 16 serving as a furnace opening flange portion. The manifold 16 is substantially cylindrical. For exchanging the outer tube 12 and the inner tube 13, the manifold 16 is detachably attached to the outer tube 12 and the inner tube 13, respectively. By supporting the manifold 16 on a housing 2 of the substrate processing apparatus 10, the process tube 11 is vertically provided on the manifold 16. Hereinafter, in the following drawings, the inner tube 13 which is a part of the process tube 11 may be omitted.

An exhaust path 17 is constituted by a gap between the outer tube 12 and the inner tube 13. The exhaust path 17 may have a circular ring shape with a constant transverse cross section. As shown in FIG. 1, one end of an exhaust pipe 18 is connected to the upper portion of the side wall of the manifold 16, and the exhaust pipe 18 communicates with the lowermost end portion of the exhaust path 17. An exhaust apparatus 19 controlled by a pressure controller 21 is connected to the other end of the exhaust pipe 18. A pressure sensor 20 is connected to an intermediate portion of the exhaust pipe 18. The pressure controller 21 is configured to feedback-control the exhaust apparatus 19 based on the measured pressure by the pressure sensor 20.

A gas introduction pipe 22 is provided below the manifold 16 so as to communicate with the furnace opening portion 15 of the inner tube 13. A source gas supply device, a reactive gas supply device and an inert gas supply device, which constitute a gas supply device 23, are connected to the gas introduction pipe 22. Hereinafter, the source gas supply device, the reactive gas supply device and the inert gas supply device are collectively referred to simply as the gas supply device 23. The gas supply device 23 is configured to be controlled by a gas flow rate controller 24. The gas supplied into the furnace opening portion 15 through the gas introduction pipe 22 flows through the process chamber 14 of the inner tube 13, and is exhausted through the exhaust path 17 and the exhaust pipe 18.

A seal cap 25, which is a furnace opening cover capable of airtightly sealing the lower end opening of the manifold 16, is provided under the manifold 16. The seal cap 25 is in contact with the lower end of the manifold 16. The seal cap 25 is disk-shaped and the diameter of the seal cap 25 is substantially equal to the outer diameter of the manifold 16. The seal cap 25 is vertically moved up and down by a boat elevator 26 protected by a boat cover 37. The boat cover 37 is provided in a standby chamber 3 of the housing 2. The boat elevator 26 includes components such as a motor-driven feed screw shaft device and a bellows. A motor 27 of the boat elevator 26 is controlled by an operation controller 28. A rotating shaft 30 is provided on the center line of the seal cap 25 so as to be rotatably supported. The rotating shaft 30 is configured to be rotationally driven by a motor 29 controlled by the operation controller 28. The boat 31 is vertically supported at the upper end of the rotating shaft 30.

The boat 31 includes a pair of end plates (an upper end plate 32 and a lower end plate 33) and a plurality of support columns 34, for example, three support columns 34 connecting the upper end plate 32 and the lower end plate 33. A plurality of support recesses 35 is engraved at each of the plurality of support columns 34 at equal intervals in lengthwise direction of each of the plurality of support columns 34. Support recesses 35 engraved at the same stage of each of the plurality of support columns 34 faces one another. By inserting the plurality of substrates 1 to the support recesses 35 of the plurality of support columns 34, the boat 31 supports the plurality of substrates 1 vertically arranged in multiple stages while the plurality of substrates 1 being in horizontal orientation. By inserting heat insulating plates 120 and heat insulating plates 122 to the support recesses 35 of the plurality of support columns 34, the boat 31 supports the heat insulating plates 120 and the heat insulating plates 122 vertically arranged in multiple stages while the heat insulating plates 120 and the heat insulating plates 122 being in horizontal orientation.

In other words, the boat 31 includes a substrate processing region between the upper end plate 32 and an end plate 38 where the plurality of substrates 1 is accommodated, and a heat insulating plate region between the end plate 38 and the lower end plate 33 where the heat insulating plates 120 and the heat insulating plates 122 are accommodated. The heat insulating plate region is provided below the substrate processing region. A heat insulating portion 36 is constituted by the heat insulating plates 120 and the heat insulating plates 122 provided between the end plate 38 and the lower end plate 32.

The rotating shaft 30 is configured to support the boat 31 while the boat 31 is lifted from the upper surface of the seal cap 25. The heat insulating portion 36 is provided in the furnace opening portion (furnace opening space) 15 and is configured to thermally insulate the furnace opening portion 15.

As shown in FIG. 2, a heater 40 as a heating mechanism is provided at the outside of the process tube 11. The heater 40 is provided concentrically with the process tube 11 and supported by the housing 2. The heater 40 is configured to heat the plurality of substrates 1 in the substrate processing region supported by the boat 31. The heater 40 includes a case 41. The case 41 is, for example, made of stainless steel (SUS). The case 41 is tubular with a closed upper end and an open lower end. Preferably, the case 41 is cylindrical. The inner diameter and the overall length of the case 41 are larger than the outer diameter and the overall length of the outer tube 12.

As shown in FIG. 2, a heat insulating structure 42 according to the embodiment is provided in the case 41. The heat insulating structure 42 according to the embodiment is tubular. Preferably, the heat insulating structure 42 is cylindrical. A sidewall portion 43 of the cylindrical heat insulating structure 42 has a multilayer structure. That is, the heat insulating structure 42 includes a sidewall outer layer 45 (hereinafter also referred to as an outer layer) provided on an outer side of the sidewall portion 43 and a sidewall inner layer 44 (hereinafter also referred to as an inner layer) provided on an inner side of the sidewall portion 43. A plurality of boundaries 105 for dividing the sidewall portion 43 into a plurality of regions in a vertical direction is provided between the outer layer 45 and the inner layer 44. A plurality of ring-shaped buffer parts 106 is also provided between the outer layer 45 and the inner layer 44 as buffer parts configured as ring-shaped ducts provided between adjacent boundaries.

As shown in FIG. 2, a check damper 104 serving as a diffusion prevention part is provided in each region of the case 41. A back-diffusion prevention part 104a is provided in the check damper 104. The back-diffusion prevention part 104a may be open or closed. Cooling air 90 is supplied to the buffer part 106 through a gas introduction path 107 by opening the back-diffusion prevention part 104a. When the cooling air 90 is not supplied from a gas source (not shown), the back-diffusion prevention part 104a is closed and acts as a lid. Accordingly, the back-diffusion prevention part 104a is formed so that an atmosphere of an internal space 75 (hereinafter also referred to as “space”) does not flow backward. The opening pressure of the back-diffusion prevention part 104a may be changed according to each region of the case 41. A heat insulating cloth 111, which is a blanket for absorbing the thermal expansion of a metal, is provided between an outer circumferential surface of the outer layer 45 and an inner circumferential surface of the case 41.

The cooling air 90 supplied to the buffer part 106 flows through a gas supply flow path 108 provided in the inner layer 44 and is supplied to the space 75 through opening holes 110 serving as opening portions which are parts of the supply path including the gas supply flow path 108. In FIG. 2, a gas supply system such as the gas supply device 23 and an exhaust system such as exhaust apparatus 19 are omitted.

As shown in FIGS. 1 and 2, a ceiling wall part 80 serving as a ceiling mechanism is provided on an upper end of the sidewall portion 43 of the heat insulating structure 42. The ceiling wall part 80 covers the space 75 to close the space 75. An exhaust hole 81, which is a part of an exhaust path which exhausts the atmosphere of the space 75, is formed in the ceiling wall part 80 to have a ring-shape. A lower end of the exhaust hole 81, which is an upstream side end of the exhaust hole 81, communicates with the inner space 75. A downstream side end of the exhaust hole 81 is connected to an exhaust duct 82.

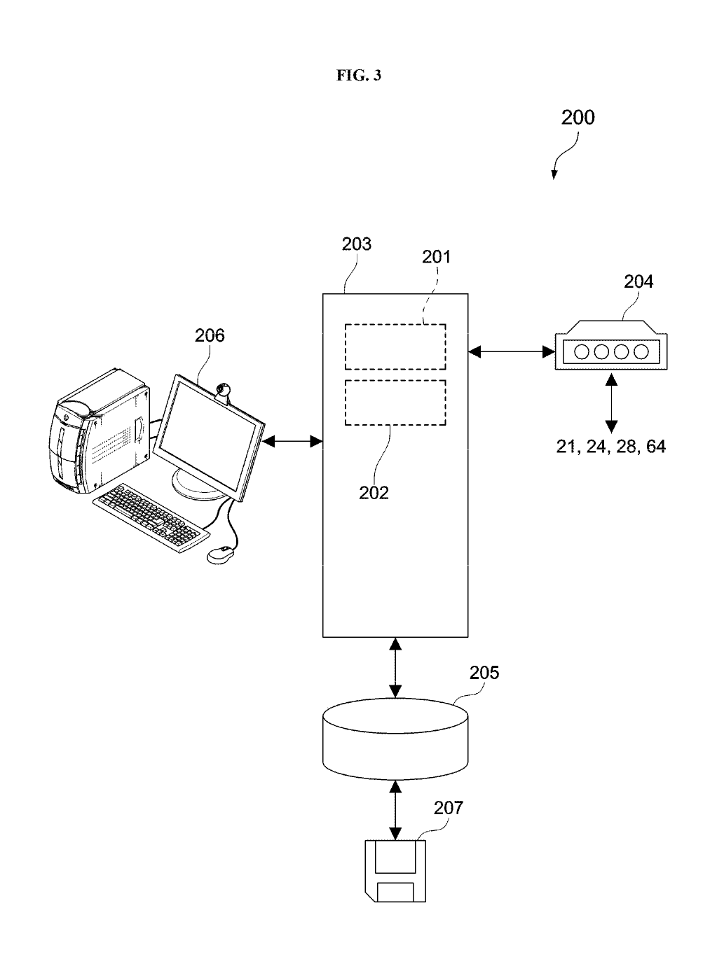

As shown in FIG. 3, a controller 200, which is a control computer serving as a control mechanism, includes a computer main body 203 including components such as a CPU (Central Processing Unit) 201 and a memory 202; a communication interface 204 serving as a communication mechanism; a memory device 205 serving as a memory mechanism; and a display/input device 206 serving as an operation mechanism. That is, the controller 200 includes components constituting a general-purpose computer.

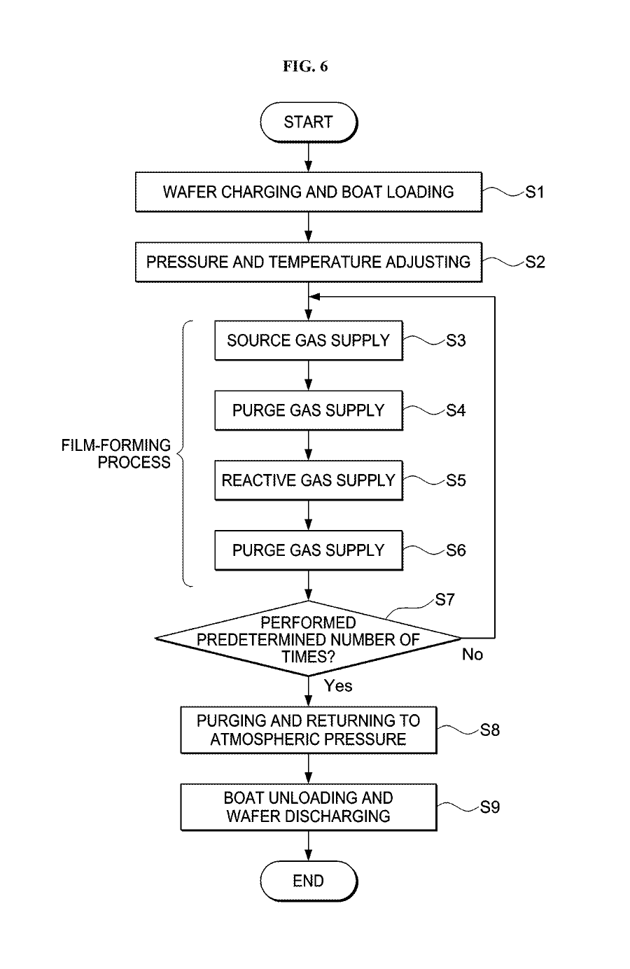

The CPU 201 forms the backbone of the controller 200. The CPU 201 is configured to execute a control program stored in the memory device 205 and a recipe stored in the memory device 205, for example, a process recipe according to an instruction from the display/input device 206. For example, the process recipe includes a temperature control process including a step S1 through a step S9 shown in FIG. 6 described later.

The memory 202 serving as a temporary memory mechanism may be embodied by components such as a ROM (Read Only Memory), an EEPROM (Electrically Erasable Programmable Read Only Memory), a flash memory, and a RAM (Random Access Memory). The RAM functions as a memory area (work area) of the CPU 201.

The communication interface 204 is electrically connected to the pressure controller 21, the gas flow controller 24, the operation controller 28 and a temperature controller 64. The pressure controller 21, the gas flow controller 24, the operation controller 28 and the temperature controller 64 may be collectively referred to simply as a sub-controller. The controller 200 can exchange data on the operation of components with the sub-controller through the communication interface 204. In the embodiment, the sub-controller includes at least a main body and may have the same configuration as that of the controller 200.

The controller 200 may be embodied by a general computer system as well as a dedicated computer system. For example, the controller 200 may be embodied by installing in a general computer a program for executing the above-described process from an external recording medium 207 such as a USB which stores the program. There are various ways to provide the program. For example, the program may be provided through the communication interface 204 such as a communication line, a communication network and a communication system. Furthermore, the program posted on a bulletin board on the communication network may be received via the network. The program provided through above-described means may be executed to perform the above-described process under an operating system just like any other application programs.

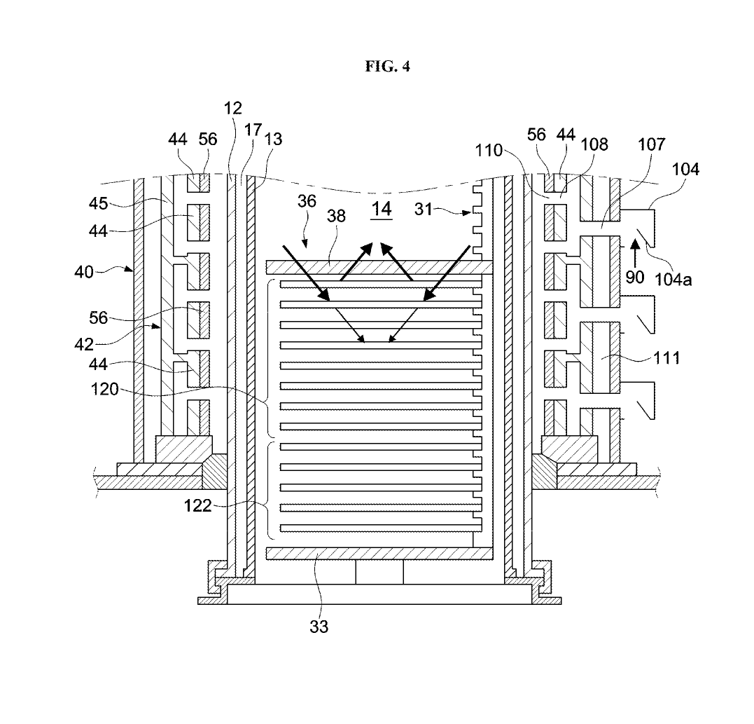

FIG. 4 is an enlarged view showing the vicinity of the heat insulating portion 36 (the heat insulating plate region) of the substrate processing apparatus 10. In FIG. 4, the gas supply system and the exhaust system are omitted. As shown in FIG. 4, the plurality of heat insulating plates 120 and the plurality of heat insulating plates 122 are provided in advance below the boat 31 before a wafer charging (substrate loading) step in which the substrates 1 to be described below are loaded in the boat 31. Accordingly, the heat insulating plate region is formed.

The plurality of heat insulating plates 120 and the plurality of heat insulating plates 122 having different levels of reflectivity are accommodated in the heat insulating plate region of the boat 31. The heat insulating plate 120 has a higher reflectivity than the heat insulating plate 122. The heat insulating plate 120 may be provided at an uppermost end of the heat insulating plate region. According to the embodiment, one heat insulating plate 120 is provided at the uppermost end of the heat insulating plate region or a plurality of heat insulating plates 120 is provided at an upper end of the heat insulating plate region. That is, the heat insulating plates 120 are provided on an upper layer portion of the heat insulating plate region.

When the heat insulating plates 120 having higher levels of reflectivity than the heat insulating plates 122 are provided on the upper layer portion of the heat insulating plate region, the levels of reflectivity in the heat insulating plate region may not be the same for each region. For example, the reflectivity of an uppermost heat insulating plate in the heat insulating plate region may be the highest and the reflectivity of the heat insulating plate provided from the uppermost end proceeding downward may become smaller. The reflectivity of the uppermost heat insulating plate in the heat insulating plate region may be the highest and the reflectivity of the plurality of heat insulating plates provided from the uppermost end proceeding downward may be gradually reduced.

As shown in FIG. 4, a heating element 56 is provided on a side surface (lateral side) of the heat insulating plate region. The plurality of heat insulating plates 120 may be provided in a portion in which the heating element 56 is provided on the side surface of the heat insulating plate region, that is, a high temperature portion of the heat insulating plate region. Accordingly, the upper layer portion of the heat insulating plate region is formed. The plurality of heat insulating plates 122 is provided in a low temperature portion of the heat insulating plate region, that is, a portion in which the heating element 56 is not provided on the side surface. Accordingly, a lower layer portion of the heat insulating plate region is formed. In other words, as shown in FIG. 4, the upper layer portion is formed by disposing the plurality of heat insulating plates 120 at a side of the substrate processing region in the heat insulating plate region and the lower layer portion is formed by disposing the plurality of heat insulating plates 122 below the upper layer portion. The levels of the reflectivity of the plurality of heat insulating plates 120 are higher than those of the reflectivity of the plurality of heat insulating plates 122 which are accumulated at a side of the furnace opening portion 15 in the heat insulating plate region.

The upper layer portion of the heat insulating plate region is a region in which the heater 40 is provided on a side surface (lateral side) of the heat insulating plate 120 accumulated in the upper layer portion. The lower layer portion of the heat insulating plate region is a region in which the heater 40 is not provided on the side surface (lateral side) of the heat insulating plate 120 accommodated in the lower layer portion. That is, the upper layer portion of the heat insulating plate region is a region in which the heater 40 horizontally surrounds the side surface of the heat insulating plate 120 accumulated in the upper layer portion. The lower layer portion of the heat insulating plate region is a region in which the heater 40 does not horizontally surround the side surface of the heat insulating plate 122 accommodated in the lower layer portion.

In the configuration shown in FIG. 4, a heat insulating plate (not shown) having a reflectivity lower than that of the heat insulating plate 120 and higher than that of the heat insulating plate 122 may be further provided. The heat insulating plate (not shown) may be provided between the upper layer portion in which the heat insulating plates 120 are provided and the lower layer portion in which the heat insulating plates 122 are provided. Accordingly, the heat insulating plate region may have a three-layer structure of an upper layer portion, an intermediate layer portion and a lower layer portion

The heater 40 (i.e., the heating element 56) is provided to surround the process chamber 14, and the substrate 1 is heated through the side thereof. Therefore, in particular, a central portion of the substrate 1 below the process chamber 14 is difficult to be heated, the temperature of the central portion of the substrate 1 is liable to decrease, the temperature of the process chamber 14 takes time to rise, and the recovery time (temperature stabilization time) tends to increase. However, as described above, the above problems may be addressed by disposing the heat insulating plate 120 having a high reflectivity on the upper layer portion of the heat insulating plate region according to the embodiment.

That is, according to the embodiment, the upper layer portion is formed by disposing the heat insulating plate 120 having a high reflectivity at the upper end of the heat insulating plate region, and thus radiant energy passing through the heat insulating plate 120 is decreased. Therefore, an amount of received heat near the central portion of the substrate 1, which is below the boat 31 and above the heat insulating plate region, may be increased. Accordingly, it is possible to reduce a temperature deviation on the surface of the substrate caused by a decrease in the temperature of the central portion of the substrate below the process chamber 14.

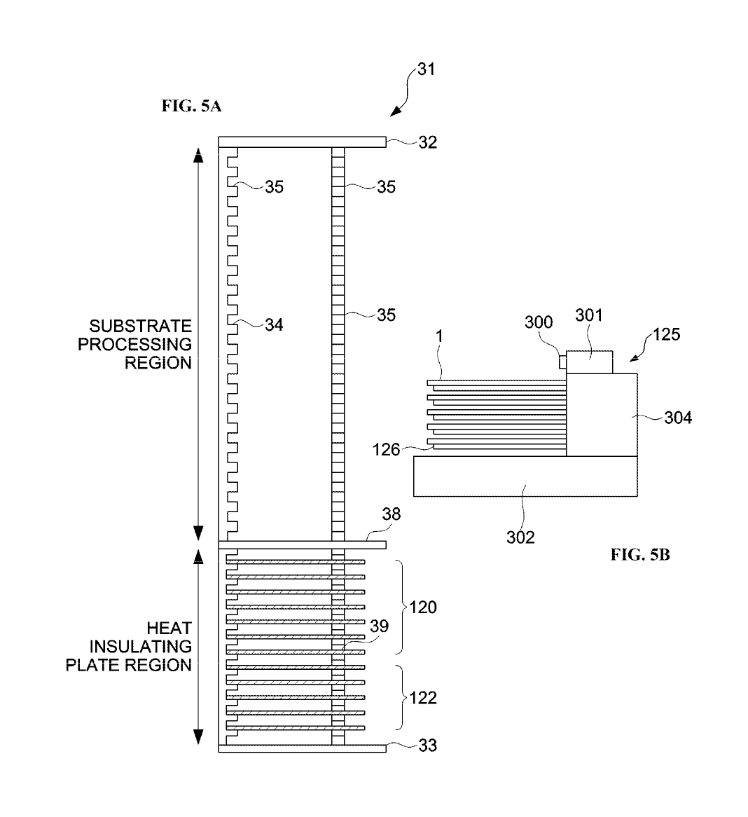

As shown in FIG. 5B, a transfer device 125 includes tweezers 126 as supports for placing and transferring the substrates 1, a detection part 300 for detecting positions at which the substrates 1 are transferred and a mechanism part 302 for operating the tweezers 126 and the detection part 300.

The mechanism part 302 is configured to be rotatable in a horizontal direction as a base of the transfer device 125.

The tweezers 126 are mounted on a fixing part 304 in order to fix a movement direction of the tweezers 126. The fixing part 304 slides on the mechanism part 302 so that the tweezers 126 are moved. The tweezers 126 are rotated by rotating the mechanism part 302 in the horizontal direction. The tweezers 126 have, for example, a U shape. A plurality of tweezers 126, for example, five tweezers, are horizontally provided. The plurality of tweezers 126 is provided at equal intervals in a vertical direction.

That is, the fixing part 304 of the transfer device 125 slides on the mechanism part 302 in forward and backward directions. The tweezers 126 are rotated in the horizontal direction (lateral direction to be described below) by the rotation of the mechanism part 302. The transfer device 125 is vertically moved by a transfer device elevator (not shown).

The detection part 300 is a sensor which optically detects the position of the substrate 1. The detection information detected by the detection part 300 is stored in the memory device 205 as position information. An operation command from a display/input device 206 is input to the controller 200, and a status obtained by the controller 200 or an encoder value obtained by the operation controller 28 are input to the memory device 205 and stored in the memory device 205. The encoder value is the number of pulses generated by the transfer device 125 and a driving motor of the transfer device elevator. Accordingly, a moving distance of the transfer device 125 [i.e., a moving distance of the tweezer 126] may be detected and an operation of the transfer device 125 may be controlled.

The controller 200 gives an operation instruction to the operation controller 28 on the basis of the position information and the encoder value which are stored in the memory device 205 and operates the transfer device 125 or the transfer device elevator. That is, as shown in FIGS. 5A and 5B, the transfer device 125 is controlled by the operation controller 28 so as to transfer the substrate 1 to the substrate processing region of the boat 31 by obtaining pieces of position information of the support recesses 35 in the substrate processing region of the boat 31.

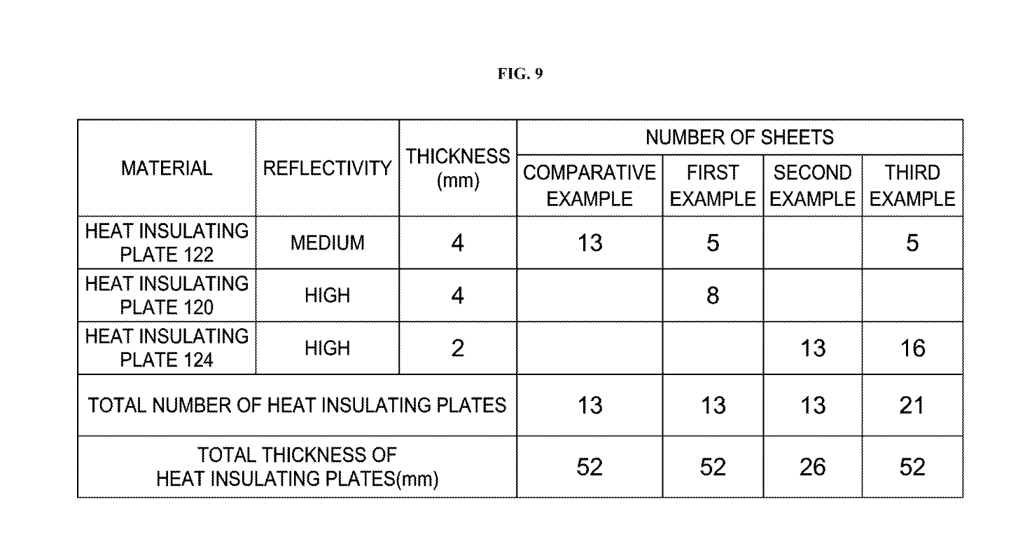

On the basis of the type and position information of the heat insulating plate and the pieces of position information of the support recesses 35 in the heat insulating plate region of the boat 31, as shown in FIG. 9 to be described below, the transfer device 125 may transfer the heat insulating plate 120 to the upper layer portion of the heat insulating plate region or transfer the heat insulating plate 122 to the lower layer portion of the heat insulating plate region.

Next, an exemplary sequence of forming a film on a substrate (hereinafter, also referred to as a “substrate processing” or a “film-forming processing”), which is one of manufacturing processes of a semiconductor device, using the substrate processing apparatus 10 will be described.

Hereinafter, an example of forming a silicon nitride film (Si₃N₄ film, hereinafter simply referred to as a SiN film) on the substrate 1 by supplying to the substrate 1 hexachlorodisilane (Si₂Cl₆, abbreviated as HCDS) gas serving as a source gas and ammonia (NH₃) gas serving as a reactive gas will be described. Hereinafter, the controller 200 and the sub-controller control the operation of the components constituting the substrate processing apparatus 10.

In the film-forming processing of the embodiment, the SiN film is formed on the substrate 1 by performing a cycle a predetermined number of times (once or more). The cycle may include a step of supplying HCDS gas onto the substrate 1 in the process chamber 14, a step of removing the HCDS gas (residual gas) from the process chamber 14, a step of supplying NH₃ gas onto the substrate 1 in the process chamber 14 and a step of removing the NH₃ gas (residual gas) from the process chamber 14. The steps in the cycle are performed non-simultaneously.

The term “substrate” is used in the same sense as “wafer” in the specification.

<Wafer Charging and Boat Loading: Step S1>

The operation controller 28 controls the transfer device 125 and the transfer device elevator (not shown) to transfer the plurality of substrates 1 in the substrate processing region of the boat 31 (wafer charging). The heat insulating plates 120 and the heat insulating plates 122 are accommodate in the heat insulating plate region of the boat 31 in advance. In the embodiment, the heat insulating plates 122 are provided in the lower layer portion of the heat insulating plate region and the heat insulating plates 120 having a higher reflectivity than that of the heat insulating plate 122 are provided in the upper layer portion of the heat insulating plate region.

Then, the operation controller 28 controls the boat elevator 26 to load the boat 31 accommodating the substrate 1, the heat insulating plates 120 and the heat insulating plates 122 into the process tube 11 and then loaded into the process chamber 14 (boat loading). The seal cap 25 then air-tightly seals the lower end of the inner tube 13 via an O-ring (not shown).

<Pressure and Temperature Adjusting: Step S2>

The pressure controller 21 controls the exhaust apparatus 19 such that the inner pressure of the process chamber 14 reaches a predetermined pressure (vacuum level). The inner pressure of the process chamber 14 is measured by the pressure sensor 20 and the exhaust apparatus 19 is feedback-controlled based on the pressure measured by the pressure sensor 20. The exhaust apparatus 19 is continuously operated at least until the processing of the substrate 1 is completed.

The heater 40 heats the process chamber 14 until the temperature of the substrate 1 inside the process chamber 14 reaches a predetermined temperature. The temperature controller 64 feedback-control the energization state of the heater 40 based on the temperature detected by a thermocouple 65 until the inner temperature of the process chamber 14 has a predetermined temperature distribution. The heater 40 continuously heats the process chamber 14 at least until the processing of the substrate 1 is completed.

The boat 31 and the substrate 1 are rotated by the motor 29. Specifically, the operation controller 28 rotates the motor 29 and the boat 31 is rotated. The substrate 1 is thereby rotated. The motor 29 continuously rotates the boat 31 and the substrate 1 at least until the processing of the substrate 1 is completed.

<Film-Forming Process>

When the inner temperature of the process chamber 14 is stabilized at a preset processing temperature, four steps described below, namely, a step S3 through a step S6, are sequentially performed.

<Source Gas Supply: Step S3>

In the step S3, the HCDS gas is supplied onto the substrate 1 in the process chamber 14.

In the step S3, the HCDS gas is supplied to the process chamber 14 through the gas introduction pipe 22. Specifically, the HCDS gas having the flow rate thereof adjusted by the gas flow rate controller 24 is supplied to the process chamber 14 of the inner tube 13, and is exhausted through the exhaust path 17 and the exhaust pipe 18. Simultaneously, N₂ gas is supplied through the gas introduction pipe 22. The N₂ gas having the flow rate thereof adjusted by the gas flow rate controller 24 is supplied to the process chamber 14 with the HCDS gas and is exhausted through the exhaust pipe 18. By supplying the HCDS gas onto the substrate 1, a silicon (Si)-containing layer having a thickness of, for example, less than one atomic layer to several atomic layers is formed as a first layer on the top surface of the substrate 1.

<Purge Gas Supply: Step S4>

After the first layer is formed on the substrate 1, the supply of the HCDS gas is stopped. The exhaust apparatus 19 vacuum-exhausts the process chamber 14 to remove residual HCDS gas which did not react or contribute to the formation of the first layer in the process chamber 14 from the process chamber 14. The N₂ gas is continuously supplied into the process chamber 14. The N₂ gas acts as a purge gas, which improves the efficiency of removing the residual HCDS gas from the process chamber 14.

<Reactive Gas Supply: Step S5>

After the step S4 is completed, the NH₃ gas is supplied onto the substrate 1, i.e. onto the first layer formed on the substrate 1 in the process chamber 14 in the step S5. The NH₃ gas is thermally activated and then supplied onto the substrate 1.

In the step S5, the NH₃ gas is supplied to the process chamber 14 through the gas introduction pipe 22. Specifically, the NH₃ gas having the flow rate thereof adjusted by the gas flow rate controller 24 is supplied to the process chamber 14 of the inner tube 13, and is exhausted through the exhaust path 17 and the exhaust pipe 18. Simultaneously, N₂ gas is supplied through the gas introduction pipe 22. The N₂ gas having the flow rate thereof adjusted by the gas flow rate controller 24 is supplied to the process chamber 14 with the NH₃ gas and is exhausted through the exhaust pipe 18. The NH₃ gas supplied onto the substrate 1 reacts with the first layer, i.e. at least a portion of the silicon-containing layer formed on the substrate 1 in the first step S3. As a result, the first layer is thermally nitrided under non-plasma atmosphere and modified into a second layer, namely, a silicon nitride (SiN) layer.

<Purge Gas Supply: Step S6>

After the second layer is formed, the supply of the NH₃ gas is stopped. The exhaust apparatus 19 vacuum-exhausts the process chamber 14 to remove residual NH₃ gas which did not react or contribute to the formation of the second layer in the process chamber 14 from the process chamber 14 in the same manner as the step S4. Similar to the step S4, it is not necessary to completely discharge the gases remaining in the process chamber 14.

<Determination: Step S7>

A cycle including the non-simultaneously performed steps S3 through S6 are performed a predetermined number of times (n times) until a SiN film having a predetermined thickness is formed on the substrate 1. It is preferable that the cycle is repeated until the second (SiN) layer having the predetermined thickness is obtained by controlling the second (SiN) layer formed in each cycle to be thinner than the second (SiN) layer having the predetermined thickness and stacking the thin second (SiN) layer by repeating the cycle. It is preferable that the cycle is performed multiple times.

<Purging and Returning to Atmospheric Pressure: Step S8>

After the film-forming process is completed, the N₂ gas is supplied into the process chamber 14 through the gas introduction pipe 22 and is exhausted through the exhaust pipe 18. The N₂ gas serves as a purge gas. Thus, the inside of the process chamber 14 is purged, and the residual gas inside the process chamber 14 or the reaction by-products are removed from the process chamber 14 (purging). Simultaneously, the cooling air 90 serving as the cooling gas is supplied to the gas introduction path 107 via the check damper 104. The supplied cooling air 90 is temporarily stored in the buffer part 106 and is ejected into the space 75 through the opening holes 110 and the gas supply flow path 108. The cooling air 90 ejected into the space 75 through the opening holes 110 is exhausted by the exhaust hole 81 and the exhaust duct 82. Then, an inner atmosphere of the process chamber 14 is replaced with an inert gas (inner atmosphere substitution) and the inner pressure of the process chamber 14 is restored to a normal pressure (returning to atmospheric pressure).

<Boat Unloading and Wafer Discharging: Step S9>

Thereafter, the operation controller 28 controls the boat elevator 26 such that the seal cap 25 is lowered by the boat elevator 26 and the lower end of the process tube 11 is opened. The boat 31 with the processed substrates 1 charged therein is unloaded from the process tube 11 through the lower end of the process tube 11 (boat unloading). The processed substrates 1 are discharged from the boat 31 (wafer discharging).

In the embodiment, the above-described manufacturing processes of a semiconductor device may further include a step (preparation step) of loading a predetermined heat insulating plate into the boat 31 before loading the substrate 1 into the boat 31 (wafer charging).

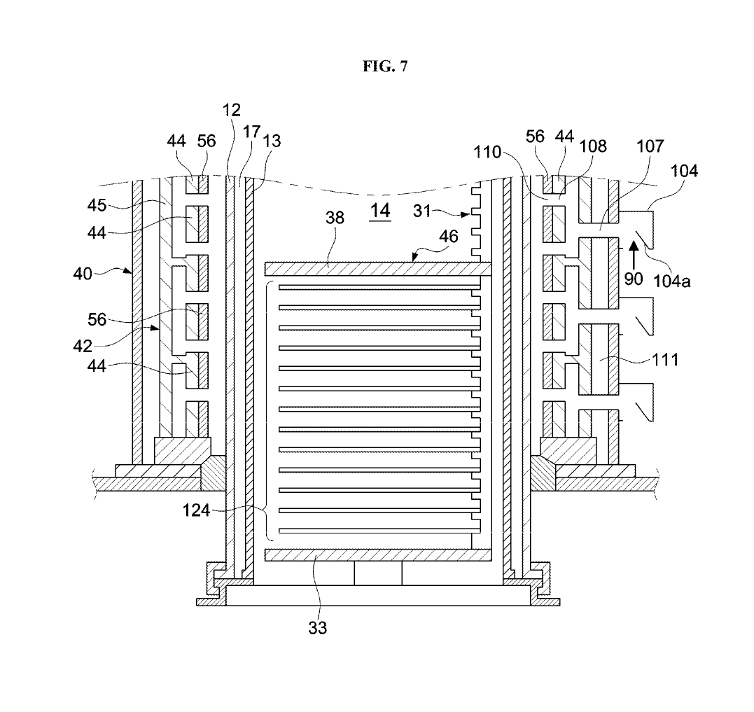

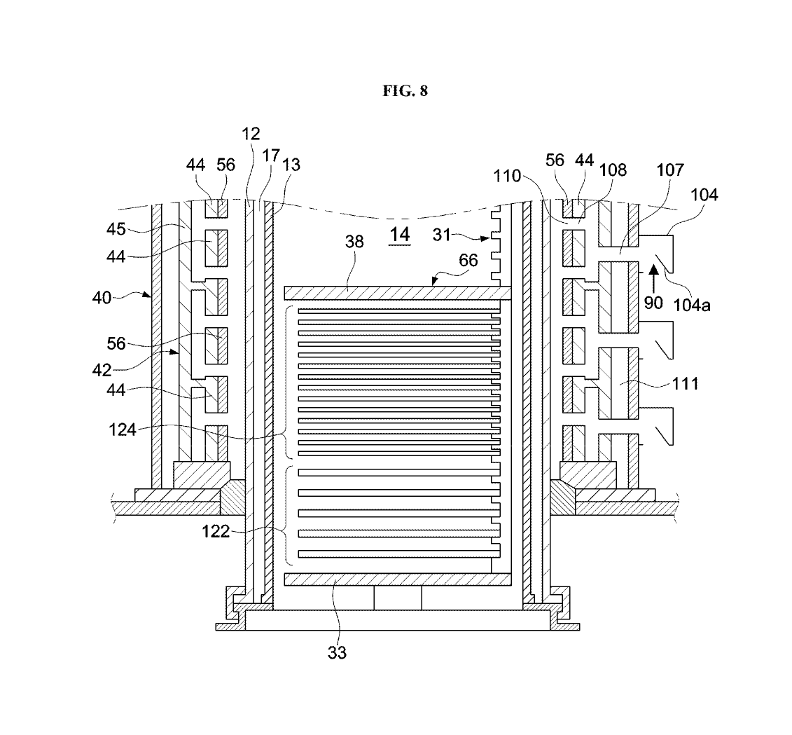

Hereinafter, modified examples of the heat insulating portion 36 of the embodiment will be described below with reference to FIGS. 7 and 8.

### First Modified Example

FIG. 7 is an enlarged view of the vicinity of a heat insulating portion 46 (a heat insulating plate region) according to a first modified example. The heat insulating portion 46 according to the first modified example is used when a temperature recovery time on a surface of a substrate is considered to be important.

The heat insulating portion 46 according to the first modified example is made of the same material as the heat insulating plate 120 described above. That is, the heat insulating portion 46 according to the first modified example has the same reflectivity as the heat insulating plate 120 described above. The heat insulating portion 46 according to the first modified example is constituted by a plurality of heat insulating plates 124 which is thinner (and thus have a smaller heat capacity) than that of the heat insulating plate 120. That is, the heat insulating plates 124 which have a high reflectivity and are thinner than the heat insulating plate 120 are provided in the heat insulating plate region in the same manner as the heat insulating plate 120 described above.

The total thickness of the heat insulating plates 124 is about a half of the total thickness of the heat insulating portion 36 which is a combination of the heat insulating plates 120 and the heat insulating plates 122 in the above embodiment. That is, by compensating for the influence of the thicknesses of the heat insulating plates with the reflectivity, the temperature deviation on the surface of the substrate is maintained equal to that of the heat insulating portion 36 of the above embodiment, but the temperature recovery time on the surface of the substrate may be shortened by about 45%.

### Second Modified Example

FIG. 8 is an enlarged view of the vicinity of a heat insulating portion 66 (a heat insulating plate region) according to a second modified example. The heat insulating portion 66 according to the second modified example is used when a temperature deviation on a surface of a substrate is considered to be important.

The heat insulating portion 66 according to the second modified example is constituted by a combination of heat insulating plates having different thicknesses and reflectivity. Specifically, a plurality of heat insulating plates 124 is provided in the heat insulating plate region in which the heating element 56 is provided on a side surface thereof, and the plurality of heat insulating plate 122 is provided in the heat insulating plate region in which the heating element 56 is not provided on a side surface thereof. A thickness of each of the plurality of heat insulating plates 124 is smaller than a thickness of each of the plurality of heat insulating plate 122. A reflectivity of each of the plurality of heat insulating plates 124 is higher than a reflectivity of each of the plurality of heat insulating plate 122. An upper layer portion of the heat insulating plate region is constituted by the plurality of heat insulating plates 124. Similar to the configuration shown in FIG. 4, a lower layer portion of the heat insulating plate region may be constituted by the plurality of heat insulating plate 122.

That is, according to the second modified example, by making the heat insulating plate 124 accumulated at a side close to the substrate processing region be thinner than the heat insulating plate 122 accumulated at a side opposite the substrate processing region and by making the reflectivity of the heat insulating plate 124 accumulated at a side close to the substrate processing region be higher than the reflectivity of the heat insulating plate 122 accumulated at a side opposite the substrate processing region, radiant energy passing through the heat insulating plate 124 may be reduced and an amount of received heat near the central portion of the substrate 1, which is below the boat 31 and above the heat insulating plate region, may be increased.

Referring to FIG. 8, the number of the heat insulating plates 124 having a high reflectivity in the heat insulating plate region is larger than the number of the heat insulating plates 122 having a low reflectivity. The number of thin heat insulating plates 124 in the heat insulating plate region is larger than the number of thick heat insulating plates 122.

Referring to FIG. 8, a distance (interval) between the heat insulating plates 124 provided at a side of the heat insulating plate region which is close to the substrate processing region is smaller than a distance (interval) between the heat insulating plates 122 accumulated at a side of the heat insulating plate region which is opposite the substrate processing region.

In this manner, by making a distance between the heat insulating plates 124 in the heat insulating plate region, which are smaller in thickness and higher in reflectivity than the heat insulating plate 122, be smaller than a distance between the heat insulating plates 122, the number of the heat insulating plates 124 constituting the upper layer portion of the heat insulating plate region is increased to be more than the number of the heat insulating plates 122 constituting the upper layer portion of the heat insulating plate region. As a result, according to the second modified example, the amount of received heat near the central portion of the substrate may be further increased as compared with the case in which the heat insulating portion 36 of the above-described embodiment is used, and thus the temperature deviation on the surface of the substrate may be further reduced and the temperature recovery time on the surface of the substrate may be further shortened.

Hereinafter, examples of the embodiment will be described with reference to FIGS. 9 through 11. However, the above-described embodiment is not limited to these examples.

### Examples

Referring to FIG. 9, in a comparative example, thirteen heat insulating plates 122 having a thickness of 4 mm were used as heat insulating portions. In a first example, the above-described heat insulating portion 36 according to the embodiment shown in FIG. 4 were used. Specifically, in the first example, eight heat insulating plates 120 having a thickness of 4 mm were provided in the heat insulating plate region to form an upper layer portion, and five heat insulating plates 122 having a thickness of 4 mm were provided in the heat insulating plate region to form a lower layer portion. In a second example, the heat insulating portion 46 according to the first modified example shown in FIG. 7 was used. Specifically, thirteen heat insulating plates 124 having a thickness of 2 mm were provided in the heat insulating plate region. In a third example, the heat insulating portion 66 according to the second modified example shown in FIG. 8 was used. Specifically, sixteen heat insulating plates 124 having a thickness of 2 mm were provided in the heat insulating plate region to form an upper layer portion, and five heat insulating plates 122 having a thickness of 4 mm were provided in the heat insulating plate region to form a lower layer portion.

In FIG. 9, the indication that the reflectivity is “high” refers to the case in which the heat insulating plate 120 and the heat insulating plate 124 reflect, for example, 80% or more of light or heat, and the indication that the reflectivity is “medium” refers to the case in which the heat insulating plate 122 reflects, for example, about 40% of light or heat.

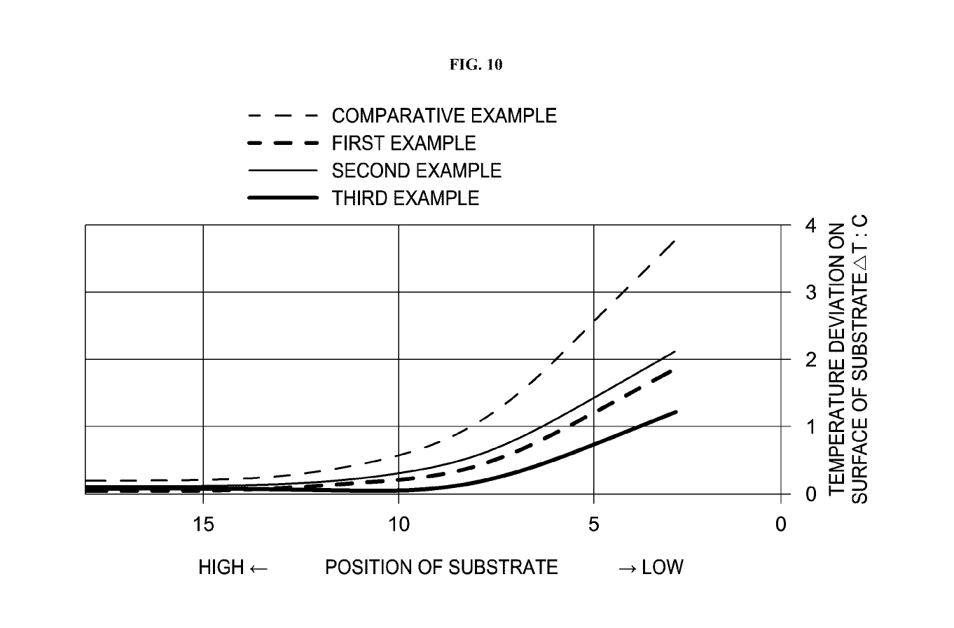

FIG. 10 is a graph showing a relationship between a position at which the substrate 1 is accommodated in the boat 31 and a temperature deviation on the surface of the substrate at a furnace temperature of 800° C. in a case in which the substrate processing described above is performed using each of the heat insulating portions in the first to third examples and the comparative example shown in FIG. 9. As shown in FIG. 10, a temperature deviation ΔT on the surface of the substrate below the boat 31 in the case using a combination of heat insulating plates having different reflectivity as in the first and third examples is about one-half to one-third of a temperature deviation ΔT on the surface of the substrate below the boat 31 in the case of using the heat insulating portion in the comparative example. Therefore, according to the first and third examples, it can be confirmed that the temperature deviation on the surface of the substrate may be improved. A temperature deviation ΔT on the surface of the substrate below the boat 31 in the case of using the thin heat insulating plate having a high reflectivity as in the second example is about one-half that in the case of using the heat insulating portion in the comparative example. Therefore, according to the second example, it can be confirmed that the substrate processing region may be further enlarged. That is, it can be confirmed that effects such as improvement in film formation uniformity by enlarging a pitch of the substrate processing region may be obtained.

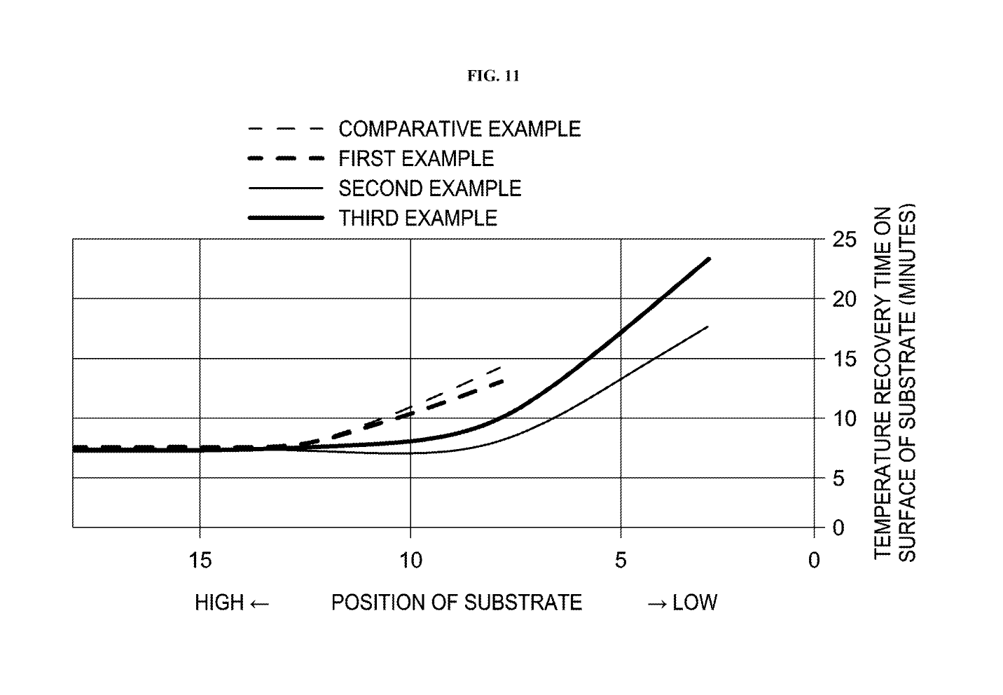

FIG. 11 is a graph showing a relationship between an accommodated position of the boat 31 of the substrate 1 and a temperature recovery time on the surface of the substrate after a furnace temperature is raised to 800° C. in a case in which the substrate processing described above is performed using the heat insulating portions in the first to third examples and the comparative example shown in FIG. 9.

As shown in FIG. 11, it can be confirmed that the temperature recovery time on the surface of the substrate provided below the boat 31 may be reduced by 45% at maximum as compared with the temperature recovery time on the surface of the substrate provided below the boat 31 in the case of using the heat insulating portion in the comparative example by using the thin heat insulating plate having a high reflectivity according to the second example or by using a combination of the heat insulating plates having different reflectivity according to the first and third examples. Therefore, a time required for the substrate processing may also be shortened.

### Other Examples

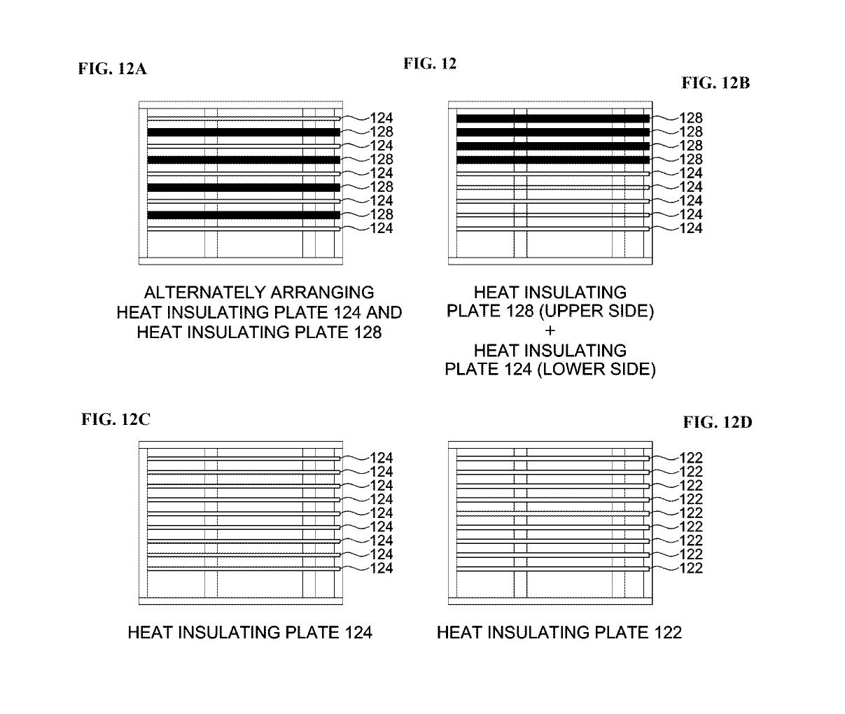

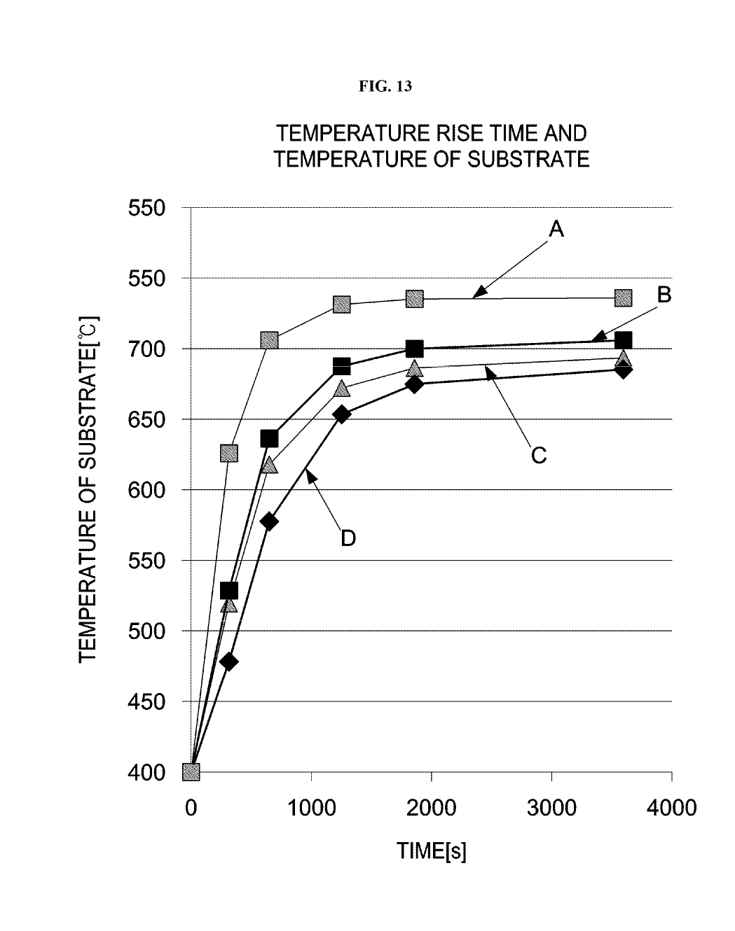

Hereinafter, other examples of the embodiment will be described with reference to FIGS. 12 and 13. Since a configuration of an apparatus according to other examples is substantially the same as the above-described embodiment, a description thereof will be omitted, and the heat insulating plate region (the heat insulating portion) of the boat 31 will be mainly described. As shown in FIG. 12, temperature of the substrate was measured for four patterns A to D. Although nine heat insulating plates are shown in the patterns A to D of FIG. 12, the number of heat insulating plates is not limited thereto. For example, as shown in the first example, thirteen heat insulating plates may be used in the patterns A to D. The heat insulating portion according to other examples with reference to the patterns A to D of FIG. 12 differs from the heat insulating portion according to the above-described examples in that a black heat insulating plate 128 for absorbing heat and light is used in other examples with reference to the patterns A to D of FIG. 12. In other examples, an optimum arrangement, a material and a thickness (heat capacity) of the heat insulating member were studied. According to other examples, the heat insulating plate 128 is configured to reflect light or heat of about several % to tens of several % compared with the heat insulating plates 122 and 124 with a thickness of 1 mm to 4 mm. For example, at room temperature, the reflectivity of the heat insulating plate 128 is about 2% to 3% with a thickness of 4 mm, about 8% with a thickness of 2 mm, and about 18% with a thickness of 1 mm. The heat insulating plate 128 has a thermal emissivity of about 70% at 600° C. or higher, and has a thermal emissivity of about 80% at 1,000° C. or higher.

As shown in FIG. 12, according to the pattern A, the heat insulating portion was formed by alternately disposing heat-insulating plates 124 of 2 mm and black heat-insulating plates 128 of 4 mm one by one (for each plate). According to the pattern B, the heat insulating portion was formed by disposing a plurality of black heat insulating plates 128 (four black heat insulating plates 128 herein) of 4 mm in the heat insulating plate region and by disposing a plurality of heat insulating plates 124 (five heat insulating plates 124 herein) of 2 mm in the heat insulating plate region. According to the pattern C, similar to the second example, the heat insulating portion was formed by disposing nine heat insulating plates 122 of 2 mm in the heat insulating plate region. According to the pattern D, similar to the above-described comparative example, the heat insulating portion was formed by disposing nine heat insulating plates 122 in the heat insulating plate region.

According to the pattern B, a region in which the black heat insulating plates 128 are provided is an upper layer portion of the heat insulating plate region, and a region in which the heat insulating plates 124 are provided is a lower layer portion of the heat insulating plate region. In the patterns, that is, the patterns A to D, a high temperature portion of the heat insulating plate region on which the heating element 56 is provided on the side surface (lateral side) may constitute an upper layer portion of the heat insulating plate region. A low temperature portion of the heat insulating plate region on which the heating element 56 is not provided on the side surface (lateral side) may constitute a lower layer portion of the heat insulating plate region.

FIG. 13 is a graph showing an example of an analysis result of temperature dependence of the substrate 1 when an initial temperature in a furnace is 400° C. and a target temperature in the furnace is 740° C. while a pressure in the furnace is maintained at 400 Pa in an N₂ atmosphere by using the heat insulating portions according to the pattern A to the pattern D shown in FIG. 12. A vertical axis in the graph of FIG. 13 represents a temperature (° C.) of the substrate 1 and a horizontal axis represents time (seconds). Here, the temperature of the substrate 1 is an average temperature on the surface of the substrate 1. The position of the substrate 1 is a predetermined position of the support recess 35 (also referred to as a “slot 5”) which is the fifth most adjacent support recess 35 from the support recess 35 (also referred to as a “slot 1”) closest to the heat insulating plate region from among the support recesses 35 formed in the support columns 34 of the boat 31. For example, in FIG. 13, the position of the substrate 1 is a position of the slot 1 closest to the heat insulating plate region from among the support recesses 35 formed in the support columns 34 of the boat 31.

The pattern C given in the above-described second example was compared with the pattern D given in the above-described comparative example with reference to FIG. 13. It can be seen that the thin heat insulating member 124 having a high reflectivity according to the pattern C maintains the temperature in the furnace at a higher temperature and a temperature rise time is faster as compared with the pattern D.

Next, the pattern C was compared with the pattern B with reference to FIG. 13. The pattern B is obtained by replacing the four heat insulating plates 124 provided in the upper layer portion of the heat insulating plate region in the pattern C with the heat insulating plates 128 using the black heat insulating material having high absorption of radiant heat. That is, according to the pattern B, the heat insulating plates 128 is provided four pieces down from the uppermost portion of the heat insulating plate region. According to the pattern B, it can be confirmed that the temperature of the substrate 1 may be raised faster to be high temperature because radiant heat is efficiently absorbed at the upper portion of the heat insulating plate region. That is, by using the black heat insulating plates 128, heat may be accumulated in the upper portion of the heat insulating plate region, it may be difficult for heat to be leaked, and the substrate 1 may be efficiently heated even at a position close to the lower portion of the substrate processing region.

Next, the pattern B was compared with the pattern A with reference to FIG. 13. The pattern A has a structure in which the black heat insulating member, that is, the heat insulating plate 128, is inserted between the heat insulating members having a high reflectivity, that is, the heat insulating plates 124. According to the pattern A, the temperature rise time is shortened and the high temperature retaining capability is improved as compared with the pattern B. It can be confirmed that the temperature of the substrate 1 may be raised faster to be high temperature because radiant heat is efficiently absorbed in the heat insulating plate region. In other words, in the pattern B, since the black heat insulating plates 128 is present only in the upper portion of the heat insulating plate region, the leakage of heat from the lower portion of the heat insulating plate region may not be suppressed. On the other hand, according to the pattern A, the leakage of heat from the entire heat insulating plate region may be suppressed by alternately disposing the heat insulating plates 124 and the black heat insulating plates 128 one by one. Characteristics which most efficiently affect the entire heat insulating plate region are the reflectivity of the black heat insulating plates 128 being low near the room temperature and thermal emissivity increasing as the temperature becomes high. Therefore, the temperature rise time may be shortened and the high temperature retaining capability may be improved in the pattern A.

As shown in FIG. 13, according to the pattern A in which the heat insulating plates 124 and the black heat insulating plates 128 are alternately provided one by one, it can be seen that the target temperature may be maintained at 740° C. According to the pattern A, the temperature rise time from the initial temperature of 400° C. to 700° C. may be made shorter than in the pattern B. According to the pattern C and the pattern D, the temperature of the substrate 1 did not reach 700° C. On the other hand, according to the pattern A and the pattern B, the temperature of the substrate 1 reached 700° C.

As described above, according to the pattern A or the pattern B of other examples, by suppressing the leakage of the heat from the heat insulating plate region (the furnace opening portion) using the heat insulating plates 128 (the black heat insulating plates) capable of absorbing light or radiant heat, the heat may be efficiently supplied to the substrate 1 below the substrate processing region. That is, by combining the heat insulating plates 124 having a high reflectivity with the black heat insulating plates 128, the temperature rise time of the substrate 1 and the retaining time at the target temperature may be controlled.

According to the embodiment and the examples, the substrate retainer is divided into the substrate processing region in which the substrate is accommodated and the heat insulating plate region in which the heat insulating plate is accommodated. The heat insulating plates having a high reflectivity and the black heat insulating plates for absorbing light may be appropriately combined and may be accommodated in the heat insulating plate region. Specifically, when the heat insulating plates having a high reflectivity and the black heat insulating plates for absorbing light are alternately accommodated in the heat insulating plate region, the time for raising the temperature of the processed substrate to the target temperature and the time for retaining the processed substrate at the target temperature may be accurately controlled.

According to the embodiment and the examples, by suppressing the leakage of heat from the heat insulating plate region (the furnace opening portion) using the black heat insulating plates 128 capable of absorbing light and radiant heat, the heat may be efficiently supplied to the substrate 1 below the substrate processing region, and an arrival time (the temperature rise time) up to the target temperature (e.g., 740° C.) may be improved. Further, by appropriately combining the black heat insulating plates 128 having a characteristic in which thermal emissivity increases as the temperature increases and the heat insulating plates having a high reflectivity, the retaining time at the target temperature of (e.g., 740° C.) may be maintained.

While the technique is described by way of the above-described embodiment and examples of the embodiment, the above-described technique is not limited thereto. The above-described technique may be modified in various ways without departing from the gist thereof.

For example, even in the case in which the temperature in the heat insulating plate region is intentionally lowered in order to suppress the heat history of the heat insulating plate region, the above-described technique may be applied. For example, by intentionally raising the heat capacity of the heat insulating plates or by selecting a material having a low reflectivity, it is possible to control the temperature of the heat insulating member region.

For example, in the above-described embodiment, the configuration in which the substrate 1 is placed on the substrate processing region of the boat 31 and the plurality of heat insulating plates 120 to 124 are placed on the heat insulating plate region of the boat 31 has been described, but the above-described technique is not limited thereto. For example, the above-described technique may also be applied to a configuration in which a heat insulating plate retainer for accommodating the heat insulating plates 120 to 124 is provided separately from the boat 31 below the boat 31.

Further, in the above-described embodiment, an example in which a SiN film is formed has been described, but the above-described technique is not limited thereto. The formed film may be a film different from the SiN film. The above-described technique may be applied to various types of films such as oxide films. The oxide films include a silicon oxide film (an SiO film) and a metal oxide film.

Furthermore, in the above-described embodiment, the substrate processing apparatus has been described, but the above-described technique is not limited thereto. The above-described technique may be applied to all semiconductor manufacturing apparatuses. The above-described technique may also be applied to an apparatus for processing a glass substrate such as a liquid crystal display (LCD) apparatus as well as the semiconductor manufacturing apparatus.

According to the technique described herein, it is possible to provide a technique capable of reducing a temperature deviation on the surface of the substrate and shortening a temperature recovery time on the surface of the substrate.

What is claimed is:

1. A substrate processing apparatus comprising:
a substrate retainer configured to accommodate a plurality of substrates and a plurality of heat insulating plates;
a reaction tube in which the substrate retainer is accommodated; and
a heating mechanism configured to heat the plurality of substrates accommodated in the substrate retainer,
wherein the substrate retainer includes a substrate processing region in which the plurality of substrates are accommodated and a heat insulating plate region in which the plurality of heat insulating plates are accommodated, and
a reflectivity of each of first heat insulating plates accommodated in an upper layer portion of the heat insulating plate region among the plurality of heat insulating plates is higher than a reflectivity of each of second heat insulating plates accommodated in a region other than the upper layer portion of the heat insulating plate region among the plurality of heat insulating plates.

2. The substrate processing apparatus of claim 1, wherein:
the heat insulating plate region is provided below the substrate processing region; and
the first heat insulating plates are provided at an uppermost portion of the heat insulating plate region.

3. The substrate processing apparatus of claim 1, wherein a thickness of each of the first heat insulating plates is smaller than a thickness of each of the second heat insulating plates.

4. The substrate processing apparatus of claim 1, wherein an interval between the first heat insulating plates is smaller than an interval between the second heat insulating plates.

5. The substrate processing apparatus of claim 4, wherein the number of the first heat insulating plates is larger than the number of the second heat insulating plates.

6. The substrate processing apparatus of claim 3, wherein the number of the first heat insulating plates is larger than the number of the second heat insulating plates.

7. The substrate processing apparatus of claim 1, wherein the upper layer portion of the heat insulating plate region is a region in which the heating mechanism is provided on a side surface of the first heat insulating plate and the lower layer portion of the heat insulating plate region is a region in which the heating mechanism does not horizontally surround the side surface of the second heat insulating plate.

8. The substrate processing apparatus of claim 1, wherein the first heat insulating plates provided in the upper layer portion of the heat insulating plate region include a black heat insulating plate for absorbing heat or light.

9. The substrate processing apparatus of claim 6, wherein the second heat insulating plates include a black heat insulating plate.

10. A substrate processing apparatus comprising:
a substrate retainer configured to accommodate a plurality of substrates and a plurality of heat insulating plates; and
a heating mechanism configured to heat the plurality of substrates accommodated in the substrate retainer,
wherein the substrate retainer includes a substrate processing region in which the plurality of substrates is accommodated and a heat insulating plate region in which the plurality of heat insulating plates is accommodated, and
heat insulating plates having a high reflectivity and black heat insulating plates for absorbing light are alternately accommodated in the heat insulating plate region.

11. A substrate retainer comprising:
a substrate processing region in which a substrate is accommodated; and
a heat insulating plate region in which a plurality of heat insulating plates are accommodated,
wherein a reflectivity of a first heat insulating plate accommodated in an upper layer portion of the heat insulating plate region among the plurality of heat insulating plates is higher than a reflectivity of a second heat insulating plate accommodated in a region other than the upper layer portion of the heat insulating plate region among the plurality of heat insulating plates.
